(19) United States
(12) Patent Application Publication
(10) Pub. No.: US 2008/0317177 A1
(43) Pub. Date: Dec. 25, 2008

(54) Wiener filtering arrangement

(75) Inventor: Pedro Hoejen-Soerensen, Allerod (DK)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: Nokia Corporation

(21) Appl. No.: 11/896,128

(22) Filed: Aug. 29, 2007

(30) Foreign Application Priority Data
Jun. 22, 2007 (GB) 0712270.8

(51) Int. Cl. H03K 5/01

(52) U.S. Cl. 375/346

(57) ABSTRACT

A Wiener filtering arrangement includes a first filter configured to output at an output first signal estimates and a polyphase filter having an input configured to receive the first signal estimates and an output. The polyphase filter is configured to use only a subset of a plurality of reference signals to provide second signal estimates at said output.

### CROSS REFERENCE TO RELATED APPLICATIONS

This application claims priority to and the benefit of Great Britain Application Serial No. 0712270.8, filed on Jun. 22, 2007. The disclosure of the prior application is hereby incorporated by reference in its entirety.

### FIELD OF THE INVENTION

The present invention relates to a Wiener filtering arrangement and to a filtering method. In particular but not exclusively embodiments of the present invention relate to a Wiener filtering arrangement for use for channel estimation in an OFDM orthogonal frequency division multiplexing system.

### BACKGROUND OF THE INVENTION

Wiener filters use a statistical approach to filter out noise that has corrupted a signal. Wiener filters assume that a signal and noise are stationary linear stochastic processes with known autocorrelation and cross-correlation. In simple terms, the input to the Wiener filter is assumed to be a signal, s(t), corrupted by additive noise, n(t). The output, x(t), is calculated by means of a filter, g(t), using the following convolution:

x(t)=g(t)*(s(t)+n(t))

where

s(t) is the original signal (to be estimated)

n(t) is the noise

x(t) is the estimated signal

g(t) is the Wiener filter

The error is e(t)=s(t+α)−x(t) and the squared error is e²(t)=s²(t+α)−2s(t+α)x(t)+x²(t) where

s(t+α) is the desired output of the filter

e(t) is the error

Depending on the value of α the problem is:

If α>0 then the problem is that of prediction

If α=0 then the problem is that of filtering

If α<0 then the problem is that of smoothing

In more detail, a finite-dimensional, linear estimation problem is one of estimating a zero-mean vector of unknowns ƒ with a linear function of a zero-mean vector of observations g, i.e.

\hat{ƒ}_{L}=Lg

is a linear estimate of ƒ and L is the matrix which maps g into \hat{ƒ}_{L}. The assumption of zero-mean results in no loss of generality because, for the case of non-zero mean, the deviation from the mean can be considered. This results in an affine estimator rather than a linear one.

The Wiener Filter/Smoother or linear-minimum-mean-squares-error (LMMSE) estimator is a linear estimator that minimizes the mean-square estimation error,

$$〈 {\vert f - {\hat{f}}_{L} \vert}^{2} 〉 .$$

It can be shown that this results in the linear estimator,

ƒ=P_{ƒg}P_{g}⁻¹g

where P_{ƒg} and P_{g} denotes the cross-covariance matrix of ƒ and g and the covariance matrix of the vector g, respectively. Consider the case where ƒ is a scalar. In order to specify the position of ƒ, the coordinate ξ is provided. The linear estimator of the function ƒ at coordinate ξ is then given by,

ƒ_{t,}=P_{ƒ}_{_{g}} ₈₆ P_{ξ}⁻¹g

P_{ƒ}_{_{g}}_{ξ}and P_{g} can be interpreted as the row-vector containing the correlation between the test point (at location ξ) and training set (at the given training set locations), and the correlation between the training set (at the training set locations).

Consider the application of Wiener Filtering (LMMSE) to the task of estimating the channel transfer function given a set of pilot-locations and raw channel estimates. In that case we have

\tilde{h}_{ξ}=h_{ξ}+ν_{ξ}

where ξ=(t, ƒ) is a time-frequency coordinate, h_{ξ}and \tilde{h}_{ξ}is the true and raw channel estimate, respectively, and ν_{ξ}is the noise associated with the coordinate ξ. It is assumed that there is a set of measurements \tilde{h}≡(\tilde{h}_{ƒ}) (the raw channel estimates). The Wiener (LMMSE) estimated channel transfer function at coordinate ξ is then given by,

h_{ξ}=Pₕ_{_{g}}ₕ(P_{ξ}+P_{ν})⁻¹\tilde{h}

Hence, the covariance function needs to be known which is given by the frequency correlation function, of the “true” channel. The Wiener filter in some sense tries to “match” the frequency correlation function; the amount by which the frequency correlation function is “matched” depends on the SNR (signal to noise ratio). In order to apply the frequency processing to the Wiener filter/smoother an estimate of the coherence BW bandwidth as well as the SNR is required.

In a typical OFDM based transceiver system the channel transfer function is sampled at a given set of time-frequency positions known as pilot locations. The task of the channel estimator is then to infer the entire channel transfer function at some other locations in the time-frequency grid given the sampled values at the pilot locations. The starting point for any interpolation based channel estimator for an OFDM transceiver system is a set of (noisy) samples of the channel transfer function evaluated at a given set of time-frequency positions Ξ⊂Ω, where Ω denotes the entire time-frequency grid of interest. Typically, these samples are obtained at the given time-frequency positions Ξ by transmitting a set of constellation points (termed pilots) which are known at the receiver side. After the FFT fast Fourier transform processing of the OFDM symbol at time t, received signal r_{t,ƒ} is available where ƒ denotes the sub-carrier index. One way of obtaining a (noisy) sample h_{t,ƒ} of the channel transfer function at pilot location (t, ƒ) is to divide the received signal r_{t, ƒ} with the associated pilot value p_{t,ƒ}, i.e. h_{t,ƒ}=r_{t,ƒ}/p_{t, ƒ}, for all (t, ƒ)εΞ.

In the following it is assumed that the set of noisy samples (h_{t,ƒ})_{(t,ƒ)εΞ} (also termed raw channel estimates) has been obtained of the channel transfer function by some means. The task is now to estimate the channel transfer function for the entire time-frequency grid of interest Ω given the raw channel estimates (h_{t,ƒ})_{(t,ƒ)εΞ} at the pilot locations Ξ; note that this also includes improving the noisy estimates of the channel transfer function at the pilot locations.

Interpolation based channel estimation can be carried out in numerous ways e.g. by simple linear interpolation between adjacent pilots or by fitting a polynomial function (for example by the least-squares method) to the sampled channel transfer function. Even though channel estimation based on simple linear interpolation is computationally tractable it tends to perform badly in channels with high frequency selectivity. A more advanced approach is to apply Wiener Filtering (or LMMSE) which relies on some statistical features of the underlying channel transfer function to be estimated. However, this approach tends to become computationally intractable even for moderately sized pilot sets.

For practical purposes the Wiener Filter solution becomes computationally intractable when the size of the pilot set has an order of magnitude of 3 or larger. Pilot sets of size 20 or less is within computational reach. For very large pilot sets a sliding window approach can be adopted in order to reduce the size of the pilot set used for evaluating the Wiener filter.

Some methods of pilot symbol processing are described in Pilot-Symbol-Aided Channel Estimation in Time and Frequency, Hoeher, P. et. al. Proc. Communication Theory Mini-Conf. (CTMC) within IEEE Global Telecommun. Conf. (GLOBECOM'97), pp. 90-96, 1997; Channel Estimation by Adaptive Interpolation, Wilhemsson, L. et al. US20050105647A1 May 19, 2005).

It is an aim of some embodiments of the present invention to address or at least mitigate one or more of the above mentioned problems.

### SUMMARY OF THE INVENTION

According to a first aspect, the present invention provides a Wiener filtering arrangement comprising:

a first filter configured to output at an output first signal estimates; and

a polyphase filter having an input configured to receive said first signal estimates and an output, said polyphase filter being configured to use only a subset of a plurality of reference signals to provide second signal estimates at said output.

According to a second aspect, the present invention provides a channel estimator comprising a Wiener filtering arrangement according to the first aspect of the present invention.

According to a third aspect, the present invention provides a method of Wiener filtering comprising:

providing first signal estimates; and

using said first signal estimates and a plurality of reference signals to provide second signal estimates.

According to a fourth aspect, the present invention provides a computer program production comprising program code means stored in a computer readable medium, the program code means being configured to perform the method of the third aspect when the program is run on a processor.

According to another aspect of the invention, there is provided a Wiener filtering arrangement comprising:

first filter means for outputting at an output first signal estimates; and

polyphase filter means for receiving said first signal estimates and for using only a subset of a plurality of reference signals to output second signal estimates

According to another aspect of the invention, there is provided a channel estimator comprising:
means for providing first channel estimates;
means for smoothing said first channel estimates to provided a smoothed output; and
means for performing polyphase filtering on said smoothed output.

According to another aspect of the invention, there is provided a channel estimator comprising:
a channel estimator configure to provide first channel estimates;
a first filter configured to smooth the first channel estimates; and
a second filter configured to polyphase filter the smoothed first channel estimates.

### BRIEF DESCRIPTION OF DRAWINGS

For a better understanding of the present invention, and as to how the same may be carried into effect, reference will now be made by way of example only to the accompanying figures in which:

FIG. 1 represents one example of a shifting structure utilized in an interpolation method embodying the present invention;

FIG. 2 shows a diagram representing the extension of embodiments of the present invention to the 2-dimensional interpolation case;

FIG. 3 shows a channel estimator embodying the present invention; and

FIG. 4 is a flow chart of an embodiment of the invention.

### DESCRIPTION OF PREFERRED EMBODIMENTS OF THE INVENTION

It should be appreciated that the term smoothing is typically used for the case where future observations are used to improve on previous observations. However, in this context of the description of some embodiments of the invention the term is more broadly used to mean any improvement made on observations based on other observations.

Embodiments of the present invention may provide a computationally efficient way for performing interpolation based channel estimation in an OFDM based transceiver system. Embodiments of the invention provide a computationally efficient way to do smoothing/interpolation of the channel transfer function by means of a two-filter approach. Embodiments of the invention may remove the undesirable estimation transient that is typical encountered at the edges of the frequency band of interest.

In embodiments of the invention the Wiener filter arrangement carries out with a first filter a smoothing operation which improves the SNR at the pilot location (observations) and then an interpolating operation with a second filter which is based on the improved observations. In other words, the first filter (denoted the pilot-filter) is applied on a set of active pilots. The second filter (denoted the sub-pilot filter) takes care of the filtering in between pilots. The pilot filter may be implemented as a shift-register which always contains the active pilots; the sub-pilot filter then controls when to put a new pilot into the shift-register.

Embodiments of invention are described for the 1-dimensional interpolation case and the 2-dimensional interpolation case. However, the described principle can straightforwardly be extended to the multi-dimensional case of two or more.

Embodiments of the invention provide a mechanism to reduce the computational complexity of the interpolation task by dividing it into two coupled sub-tasks.

Reference is made to FIG. 4 which shows a method embodying the invention. The interpolation task is split into two.

In operation S1, there is determined a vector e=cᵢ of “raw” channel estimates given by cᵢ=(hᵢ hᵢ₊₁ hᵢ₊₂ . . . h_{i+L-1})^{T}. hᵢ thus denotes the raw channel estimate associated with the pilot number i=0, 1, 2, . . . , N−1, where N is the total number of pilots in the OFDM symbol. It is assumed that the pilots are regularly spaced by Δ sub-carriers; in the case where the pilot spacing is regular except at a few locations it is possible to fill in channel estimates at the “missing” pilot locations (say by simple linear interpolation) before invoking the interpolation mechanism embodying the present invention. The pilot separation midpoint, Λ_{Δ} is defined as the integer half of the pilot separation Δ. Similarly the pilot filter midpoint, Λ_{P}, is defined as the integer half of L−1 (when indexing from 0), where L denotes the filter size.

In operation S2, which is the first operation of the interpolation task, the vector e of “raw” channel estimates is processed by a vector filter M which yields the output g=Me.

eᵢ=(hᵢ hᵢ₊₁ hᵢ₊₂ . . . h_{i+L-1})^{T} denotes the (L×1)-vector of currently used (active) raw channel estimates and gᵢ=Meᵢ denotes the corresponding (L×1)-vector output of the matrix filtering. This is smoothing.

For any sub-carrier index ƒ the associated triplet is (λ_{bfr}, λ_{wfr}, λ_{wfo}) where λ_{bfr}, λ_{wfr} and λ_{wfo} is the “between filter reference”, “within filter reference” and “within filter offset”, respectively. The “between filter reference” is the (global) pilot index of the first active pilot (this information relates to the active pilot block). The “within filter reference” is the (local) pilot index of the closest pilot to the sub-carrier ƒ. The “within filter offset” is the index distance from the “within filter reference” to the sub-carrier ƒ.

Operation S2 may be performed by a smoothing matrix M which smoothes the raw channel estimates at pilot positions, ending up in vector g. The matrix M may be the inverse of (R+identity_matrix/SNR) where R is the matrix containing the frequency correlations between all the pilots that are used in the “matrix” filtering. Note that in the case where the pilots are regular spaced, it is only necessary to store one common matrix (a shift of the active set of pilots would result in the same frequency correlation matrix). A filter-bank of pre-computed matrix filters may be used. It should be appreciated that the filter used may depend on the estimated coherence bandwidth and SNR.

In operation S3, the computed triplet and g_{λ}_{_{bfr}} is then used to carry out poly-phase filtering. This is the second interpolation. In operation S3 the output g of the vector filter is processed by a poly-phase filter until a point is reached where e=cᵢ₊₁ and the process is repeated, etc. The interpolation process is initialized with i=0. and ends with i=N−L where N denotes the total number of pilots in the OFDM symbol; alternatively, the interpolation process can be carried out in reverse order by initializing i=N−L and then decrement the index when going from operation two to one. The output of the polyphase filter is an improved channel estimate. The output of the polyphase filter is the interpolated output. Polyphase filters mean that the input is presented to different filters, e.g. say that the input is x y z then the output could be something like x1 x2 x3 y1 y2 y3 z1 z2 z3; 3 values go in and 9 values go out. Interpreted in another way, the input is given by x o o y o o z o o where o denotes missing values then the interpolated output is given by x1 x2 x3 y1 y2 y3 z1 z2 z3. So the output is an interpolated version of the input.

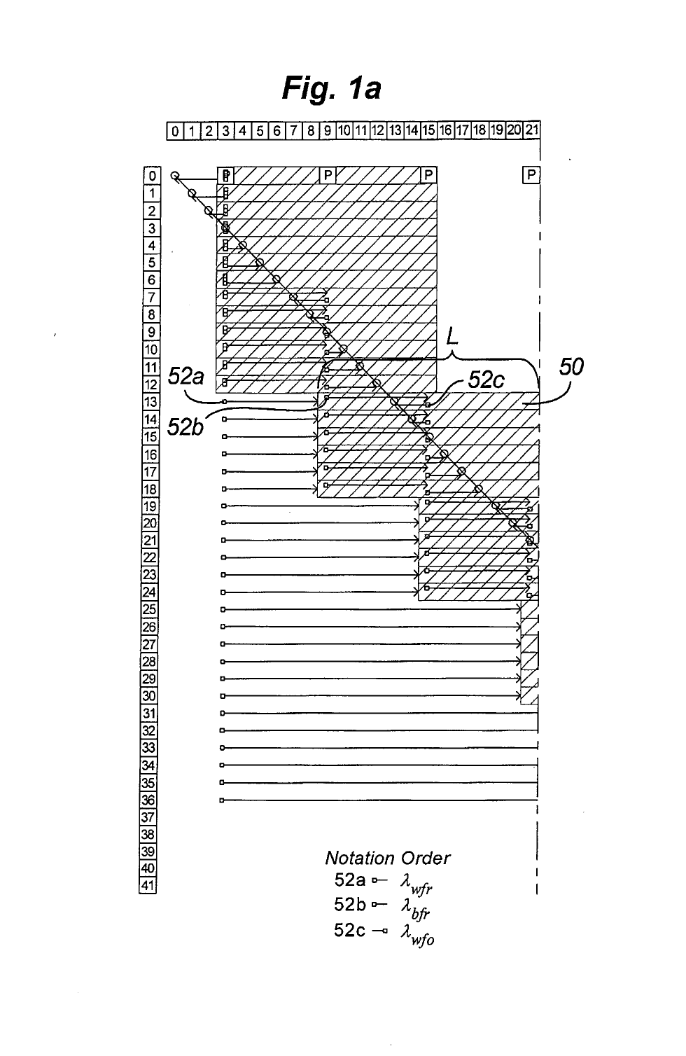

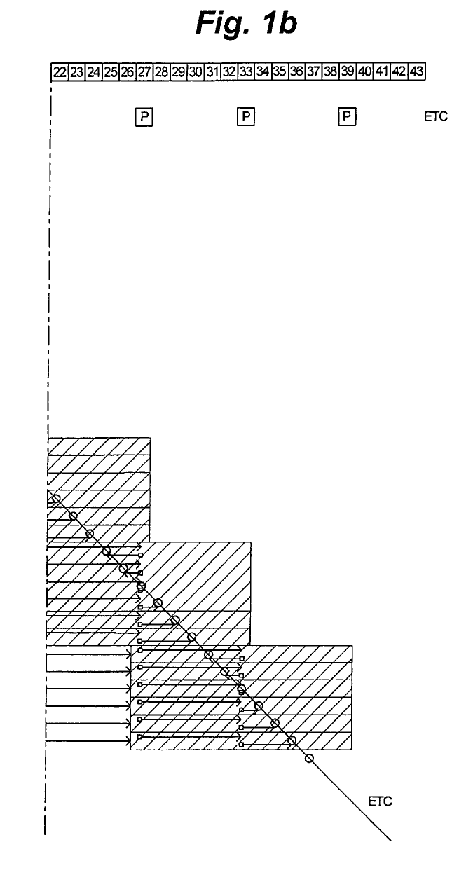

After poly-phase filtering the “within filter offset” is incremented by one in operation S4. The value of i also determines how many outputs the polyphase filter produces. See for example FIG. 1. In the case where i=0 the polyphase filter produces 13 outputs before the i index is incremented. However, in the case i=1 the polyphase filter only produces 6 outputs. The incremented value of i is therefore used in operation S1 and operation S3.

The described operations are then repeated for all valid sub-carrier locations in a natural order. For any new increment of ƒ the associated triplet needs to be evaluated. One way to do this is to use the following rule. If the “within filter offset” λ_{wfo} exceeds the pilot separation midpoint Λ_{Δ} then increment the “within filter reference” by 1 and decrement the “within filter offset” by the pilot separation Δ. Next, check if the updated “within filter reference” λ_{wfr} exceeds the pilot filter midpoint Λ_{P}. If that turns out to be the case then start by incrementing the “between filter reference” by one and decrement the “within filter reference” also by one; this is followed by a test to see if there are any new pilots left. If that is the case then the active block of pilots e_{λ}_{_{bfr}} is updated and pilot filtering is carried out in order to obtain g_{λ}_{_{bfr}}=Me_{λ}_{_{bfr}}. In the case where there are not any new pilots left, the last updates are skipped and the original references are kept.

Implementing the interpolation based channel estimator in this two-operation way may remove the performance degrading estimation transients typically encountered in ordinary filter approaches. If not dealt with, these transients will tend to reduce the spectral efficiency at spectral edges; this is especially true when the pilot separation is large.

It should be appreciated that the actual synthesis of the vector filter and the poly-phase filter can be designed in numerous ways by the man skilled in the art using any one or more of the know techniques for dealing with this.

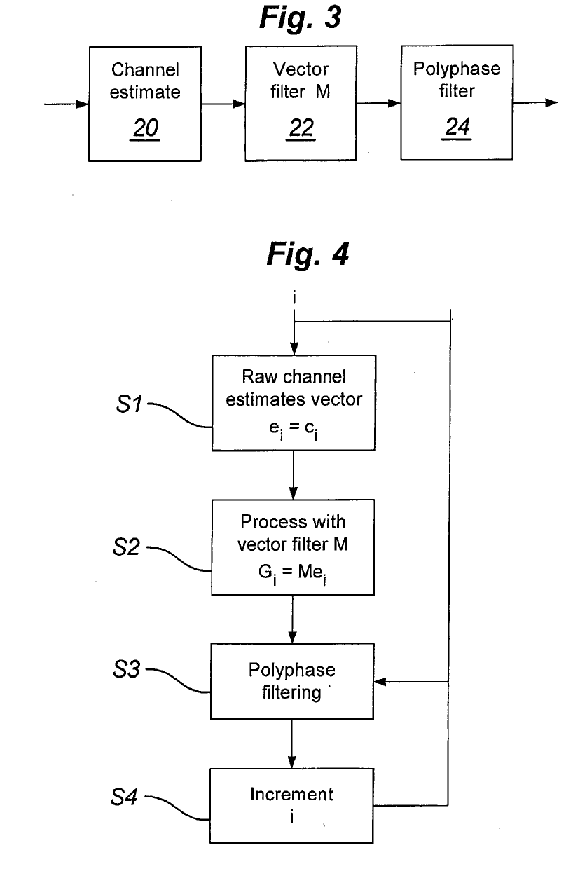

Reference is made to FIG. 3 which shows a channel estimator embodying the present invention. Block 20 provides the raw channel estimates. The output of block 20 is input to a vector filter M 22 which operates as outlined above. The output of the vector filter is arranged to be input to a polyphase filter 24 which again operates as described above. It should be appreciated, that a plurality of vector filters and polyphase filters may be provided in parallel so that more than one subcarrier frequency can be processed at the same time. Alternative the vector filter and polyphase filter may be constructed so that they can process more than one subcarrier at the same time.

Below is the pseudo code for implementing the shifting mechanism of the channel interpolator.

| | |
|---|---|
| INITIALIZE PILOT_SEPARATION_MIDPOINT | = floor(PILOT_SEPARATION/2.0); |
| INITIALIZE PILOT_FILTER_MIDPOINT | = floor((FILTER_SIZE−1)/2); |

// BASE CASE PILOT FILTERING
INITIALIZE ACTIVE_PILOT_VECTOR = THE FIRST FILTER_SIZE PILOTS;
PILOT_FILTER_RESULT=PILOT_FILTERMATRIX*ACTIVE_PILOT_VECTOR;
// INITIALIZE TRIPLET

| | |
|---|---|
| INITIALIZE BETWEEN_FILTER_REFERENCE | = 0; |
| INITIALIZE WITHIN_FILTER_REFERENCE | = 0; |
| INITIALIZE WITHIN_FILTER_OFFSET | = − DISTANCE TO FIRST PILOT LOCATION; |

```
FOR ALL SUB-CARRIERS DO {
    IF WITHIN_FILTER_OFFSET > PILOT_SEPARATION_MIDPOINT {
        // THE WITHIN FILTER REFERENCE AND WITHIN FILTER OFFSET MUST BE UPDATED
        DECREMENT WITHIN_FILTER_OFFSET BY THE PILOT SEPARATION;
          INCREMENT WITHIN_FILTER_REFERENCE;
    }
    IF WITHIN_FILTER_REFERENCE > PILOT_FILTER_MIDPOINT {
          // THE BETWEEN FILTER AND WITHIN FILTER REFERENCE MUST BE UPDATED
        INCREMENT BETWEEN_FILTER_REFERENCE;
          DECREMENT WITHIN_FILTER_REFERENCE;
          // PERFORM PILOT FILTERING //
          IF BETWEEN_FILTER_REFERENCE < TOTAL_NUMBER_OF_PILOTS−(FILTER_SIZE−1) {
                SET ACTIVE_PILOT_VECTOR
                PILOT_FILTER_RESULT=PILOT_FILTERMATRIX*ACTIVE_PILOT_VECTOR;
          } ELSE {
                DECREMENT BETWEEN_FILTER_REFERENCE;
                INCREMENT WITHIN_FILTER_REFERENCE;
          }
    }
    // PERFORM SUB-PILOT FILTERING //
    VAR=0.0;
    FOR (K=0;K<FILTER_SIZE;K++) {
          INDEX= WITHIN_FILTER_OFFSET+ PILOT_SEPARATION *(WITHIN_FILTER_REFERENCE−K);
          IF (INDEX<0) {
                    TMP=CONJUGATE SUBPILOT_FILTER[−INDEX];
        } ELSE {
                    TMP=SUBPILOT_FILTER[INDEX];
    }
    VAR=VAR+SUBPILOT_FILTER*PILOT_FILTER_RESULT[K]
    }
    CHANNEL ESTIMATE AT CURRENT SUB-CARRIER = VAR;
    INCREMENT WITHIN_FILTER_OFFSET;
} // all sub-carriers
```

An example of the shifting structure used in an embodiment of the invention is shown in FIG. 1. L=3 (this means that the filter size is 3 and that 3 pilots are used) and Δ=6 (this means that there is a pilot separation of 6 subcarriers). The numbers across the top denotes the sub-carrier index and the “P” boxes indicate the location of the pilots which have a separation of 6 sub-carriers. The numbers in the column indicates the current sub-carrier index at which the channel estimation is being done. In each row the box 50 indicates which of the pilots are being used by the pilot filtering matrix. Furthermore, each row contains three boxes 52 which indicates the state of the auxiliary filtering variables; from left to right the boxes 52 indicates the “within filter reference”, “between filter reference” and “within filter offset”, respectively.

Consider row 13, by way of example. This represents the 14^{th} sub-carrier. The Pilots used are those of the 9^{th}, 15^{th} and 21^{st} sub-carriers. Box 52a represents the first pilot of the 3^{rd} sub-carrier, that is the global pilot index. Box 52b represents the closest pilot, that of the 9th^{h} sub-carrier to the global carrier and box 52c represents the offset between the closest pilot to the 14^{tth} sub-carrier (that is the 15th sub-carrier) and the 14^{th} sub-carrier.

52a indicates the number of pilot increments from the first “global” pilot (indicated by square) to the first pilot in the active window (indicated by the end of arrow). For position 13, 52a=pilot index 1−pilot index 0=1 pilot distance=6 sub-carriers. This quantity is counted in term of pilot distances.

52b indicates the numbers of pilot increments from the first pilot in the active windows (indicated by square) to the “closest pilot” (indicated by end of arrow). For position 13, 52b=pilot index 2−pilot index 1=1 pilot distance=6 sub-carriers. Note that pilot index 2 is equivalent to subcarrier index 15 and pilot index 1 is equivalent to subcarrier index 9. The difference between the end (arrow head) and the beginning (square) of the arrow is determined. This quantity is counted in terms of pilot distances.

52c indicates the number of sub-carriers from the “closest pilot” (indicated by square) to the current sub-carrier index at which the channel estimation is being done (indicated by end of arrow). For position 13, then 52c=subcarrier index 13−subcarrier index 15=−2 subcarriers. This quantity is counted in terms of subcarrier indices.

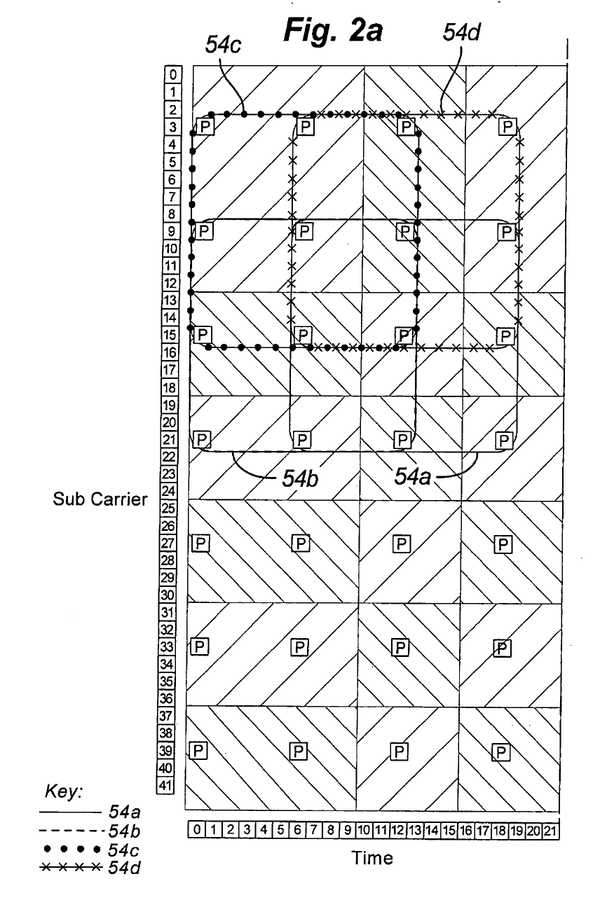

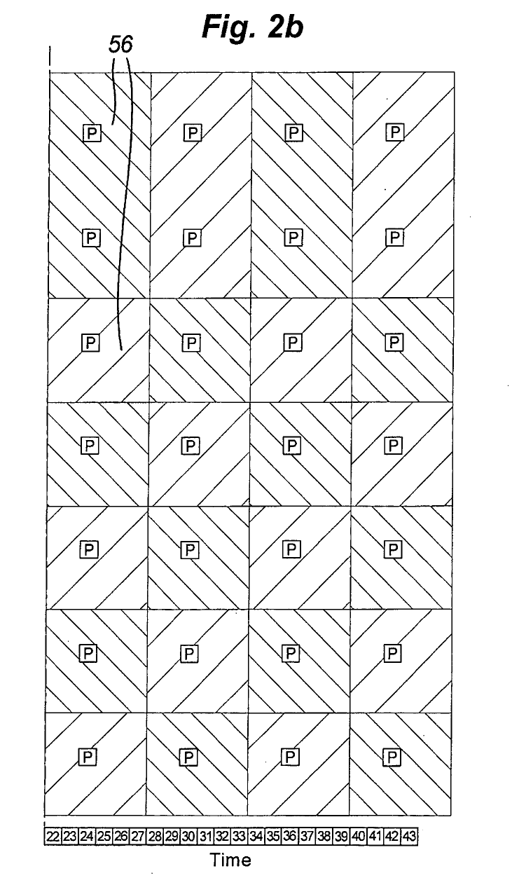

Reference is now made to FIG. 2 which shows a sketch of the concept for the 2-dimensional interpolation case where the two dimensions refer to the frequency and time dimension. Embodiments of the invention split the interpolation task into two coupled sub-tasks, namely the pilot filtering (by a matrix filter) task and the poly-phase filtering task. FIG. 2 illustrates a scenario where both the frequency and temporal separation between pilots is 6. In this example both the frequency and temporal filter covers three pilots, i.e. the resulting pilot window 54 is of size 9×9. In the arrangement of FIG. 2 four windows 54a, 54b, 54c and 54d are illustrated. The difference between the 2-dimensional case and the 1-dimensional is now that the “between filter reference”, “within filter reference” and “within filter offset” becomes 2-dimensional coordinates. In other words the pilot windows 54 are analogous to the rows 52. In order to keep the computational complexity as low as possible it is desirable to complete the poly-phase filtering of one entire region (the checker board pattern) before moving on to the next region. Each field 56 in the checker board of FIG. 2 shows the frequency-time regions where the output vector of the pilot filtering is constant. The output vector within each field is then filtered by a poly-phase filter along similar lines as in the 1-dimensional case; however, in this case an additional set of variables in order to index into the 2-dimensional poly-phase filter may be required.

Embodiments of the invention may be used in 3.9G (3GPP (Third Generation Partnership Project) Long Term Evolution.

Embodiments of the invention thus only use a limited set of the closest pilots and not all the pilots at all the frequencies. By implementing the Wiener filtering as described above, good performance can be achieved at a smaller computational and memory cost as compared to the prior art.

Embodiments of the present invention may reduce the overall computational complexity is reduced by utilization of a two-filter approach in which a matrix filter and a poly-phase filter is controlled by the shifting mechanism embodying the present invention. Furthermore, by splitting the interpolation task into two sub-tasks may enable the removal of the performance degrading filtering transients that are undesirable features of common filtering approaches.

Embodiments of the invention can be implemented in hardware and/or software. Accordingly embodiments of the present invention may at least partially implement the method, for example as shown in FIG. 4, by means of a computer program having one or more computer executable instructions.

The described embodiments have been Wiener filter. However, embodiments may be applied to other suitable filters. For example, embodiments of the invention may be applied to transform domain channel estimation (see e.g. “A low complexity ML channel estimator for OFDM, Luc Deneire et al. Communications, IEEE Transactions vol 51, issue 2, February 2003.)

Embodiments of the invention may be applied to filters where it is appropriate to have a filter structure in which the noise is reduced on the raw channel estimates at the pilot locations, and then interpolation is performed based on the output. In other words, in general there is, h_pilot_processed=F(h_pilot_raw) and h_all=G(h_pilot_processed) where F and G are vector functions.

Embodiments of the invention are appropriate for OFDM based systems. Alternative embodiments of the invention may apply to other interpolations systems where, for example, there is a regular spaced set of observations and the correlation function is “localized”.

Embodiments of the invention may be used in user equipment such as a mobile telephone, PDA (personal data assistant), portable computer, laptop, PC or the like. Embodiments of the invention may alternatively or additionally used in a base station.

1. A Wiener filtering arrangement, comprising:
a first filter configured to output first signal estimates; and
a polyphase filter comprising an input configured to receive said first signal estimates and an output, said polyphase filter being configured to use only a subset of a plurality of reference signals to provide second signal estimates at said output.

2. The Wiener filter arrangement as claimed in claim 1, wherein said second signal estimates comprise channel estimates.

3. The Wiener filter arrangement as claimed in claim 1, wherein said plurality of reference signals comprise pilot signals.

4. The Wiener filter arrangement as claimed in claim 1, wherein said polyphase filter is configured to interpolate said first signal estimates.

5. The Wiener filter arrangement as claimed in claim 1, wherein said first filter comprises an input, said input configured to receive third signal estimates, and wherein said first filter is further configured to smooth said third signal estimates to provide said first signal estimates.

6. The Wiener filter arrangement as claimed in claim 1, wherein said first filter is further configured to use all of said reference signals.

7. The Wiener filter arrangement as claimed in claim 5, wherein said third signal estimates comprise a vector given by cᵢ=(hᵢ hᵢ₊₁ hᵢ₊₂ . . . h_{i+L-1})^{T} where hᵢ is an estimate associated with the a reference signal number i=0, 1, 2, . . . , N−1, and where N is a total number of reference signals.

8. The Wiener filter arrangement as claimed in claim 1, wherein said first filter comprises a shift register.

9. The Wiener filter arrangement as claimed in claim 1, wherein said first filter comprises a smoothing matrix which is an inverse of (R+identity_matrix/signal to noise ratio), where R is a matrix comprising correlations between all the reference signals.

10. The Wiener filter arrangement as claimed in claim 1, wherein said polyphase filter is configured to use at least one of: an index of a first active reference signal, an index of a closest reference signal, and a distance to said closest reference signal to provide said second signal estimates.

11. The Wiener filter arrangement as claimed in claim 1, wherein said polyphase filter is configured to provide said second signal estimates for a plurality of carrier signals.

12. The Wiener filter arrangement as claimed in claim 1, wherein said second signal estimates comprise channel estimates for an orthogonal frequency division multiplexing system.

13. A channel estimator, comprising:
a Wiener filtering arrangement, comprising:
a first filter configured to output first signal estimates; and
a polyphase filter comprising an input configured to receive said first signal estimates and an output, said polyphase filter being configured to use only a subset of a plurality of reference signals to provide second signal estimates at said output.

14. A method of Wiener filtering, comprising:
providing first signal estimates; and
using said first signal estimates and a plurality of reference signals to provide second signal estimates.

15. The method as claimed in claim 14, wherein using said first signal estimates and said plurality of reference signals provides second signal estimates comprising channel estimates.

16. The method as claimed in claim 14, wherein said plurality of reference signals comprise pilot signals.

17. The method as claimed in claim 14, where using said first signal estimates and said plurality of reference signals to provide second signal estimates comprises interpolating said first signal estimates.

18. The method as claimed in claim 14, further comprising:
smoothing third signal estimates to provide said first signal estimates.

19. The method as claimed in claim 18, wherein smoothing said third signal estimates comprises using all of said reference signals.

20. The method as claimed in claim 18, wherein smoothing said third signal estimates comprises smoothing said third signal estimates comprising a vector given by cᵢ=(hᵢ hᵢ₊₁ hᵢ₊₂ . . . h_{i+L-1})^{T}, where hᵢ is an estimate associated with the a reference signal number i=0, 1, 2, . . . , N−1, and where N is a total number of reference signals.

21. The method as claimed in claim 18, wherein smoothing said third signal estimates comprises using a smoothing matrix which is an inverse of (R+identity_matrix/signal to noise ratio), where R is a matrix comprising correlations between all said reference signals.

22. The method as claimed in claim 14, further comprising:
using at least one of an index of a first active reference signal, an index of a closest reference signal, and a distance to said closest reference signal to provide said second signal estimates.

23. The method as claimed in claim 14, wherein using said first signal estimates and a plurality of reference signals to provide second signal estimates comprises providing said second estimates for a plurality of carrier signals.

24. The method as claimed in claim 14, wherein using said first signal estimates and said plurality of reference signals provides second signal estimates comprising channel estimates for an orthogonal frequency division multiplexing system.

25. A computer program embodied on a computer readable medium, the computer program being configured to control a processor to perform:
providing first signal estimates; and
using said first signal estimates and a plurality of reference signals to provide second signal estimates.

26. A Wiener filtering arrangement, comprising:
first filter means for outputting output first signal estimates; and
polyphase filter means for receiving said first signal estimates and for using only a subset of a plurality of reference signals to output second signal estimates.

27. A channel estimator, comprising:
estimator means for providing first channel estimates;
first filter means for smoothing said first channel estimates to provide a smoothed output; and
second filter means for performing polyphase filtering on said smoothed output.

28. A channel estimator, comprising:
a channel estimator configured to provide first channel estimates;
a first filter configured to smooth said first channel estimates; and
a second filter configured to polyphase filter said smoothed first channel estimates.
